(19) United States
(12) Patent Application Publication
(10) Pub. No.: US 2017/0287728 A1
(43) Pub. Date: Oct. 5, 2017

(54) METHODS FOR METALIZING VIAS WITHIN A SUBSTRATE

(71) Applicant: CORNING INCORPORATED, CORNING, NY (US)

(72) Inventors: Rachel Eileen Dahlberg, Corning, NY (US); Shrisudersan Jayaraman, Horseheads, NY (US)

(21) Appl. No.: 15/471,401

(22) Filed: Mar. 28, 2017

Related U.S. Application Data
(60) Provisional application No. 62/315,146, filed on Mar. 30, 2016.

(51) Int. Cl. H01L 21/48; C25D 7/12; C25D 3/38; H01L 21/683; H01L 23/498

(52) U.S. Cl. CPC H01L 21/486; H01L 21/6835; H01L 23/49894; H01L 23/49866; H01L 23/49827; C25D 3/38; C25D 7/123; H01L 2221/68359

(57) ABSTRACT

Methods of metalizing vias within a substrate are disclosed. In one embodiment, a method of metalizing vias includes disposing a substrate onto a growth substrate. The substrate includes a first surface, a second surface, and at least one via. The first surface or the second surface of the substrate directly contacts a surface of the growth substrate, and the surface of the growth substrate is electrically conductive. The method further includes applying an electrolyte to the substrate such that the electrolyte is disposed within the at least one via. The electrolyte includes metal ions of a metal to be deposited within the at least one via. The method also includes positioning an electrode within the electrolyte, and applying a current and/or a voltage between the electrode and the substrate, thereby reducing the metal ions into the metal on the surface of the growth substrate within the at least one via.

### CROSS-REFERENCE TO RELATED APPLICATIONS

This application claims the benefit of priority under 35 U.S.C. §119 of U.S. Provisional Application Ser. No. 62/315,146 filed on Mar. 30, 2016 the content of which is relied upon and incorporated herein by reference in its entirety.

### BACKGROUND

### Field

The present specification generally relates to methods for metalizing vias within a substrate and, more specifically, to metalizing vias within a substrate using a seedless electroplating process.

### Technical Background

Metallization is a process in semiconductor and microelectronics industries that allows through-substrate vias to act as electrical interconnects. Copper is one preferred metal due to its low electrical resistivity. Through hole connections have garnered interest in recent years as they enable thin silicon and glass via-based technologies that provide high packaging density, reduced signal path, wide signal bandwidth, lower packaging cost and extremely miniaturized systems. These three-dimensional technologies have wide range of applications in consumer electronics, high performance processors, micro-electromechanical devices (MEMS), touch sensors, biomedical devices, high-capacity memories, automotive electronics and aerospace components.

Current processes available for filling vias with copper include chemical vapor deposition (CVD), paste-based process, and electroplating. The CVD process is suited for small sized vias (3-5 μm diameter) with aspect ratios up to 20, but is not suitable for vias that are larger and deeper. The paste process consists of filling the vias with a paste containing copper and a suitable binder, followed by curing at about 600° C. in an inert atmosphere to prevent oxidation. The substrate (e.g., glass) is then subsequently polished or thinned to account for a 2-8 μm shrinkage of the copper fill during curing. High temperature curing poses the risk of breaking or bending of low-thickness glasses, in addition to the need to manage coefficient of thermal expansion (CTE) of the paste during curing which may lead to copper lifting from vias. Both the CVD process and the paste process are not manufacture-friendly due to their complexity and high cost.

Current electroplating processes to fill vias includes depositing barrier and seed layers onto the substrate and in the vias, followed by electrodeposition of copper and finally thinning Depositing the barrier and seed layers is difficult and not cost-effective for large scale manufacturing. Further, obtaining a void-free fill is challenging in a seeded electroplating process, as the deposition front is non-uniform along the depth of the via and renders itself to formation of voids.

Accordingly, a need exists for a process to metalize vias within a substrate that is simple, scalable and low-cost.

### SUMMARY

In a first aspect, a method of metalizing vias includes disposing a substrate onto a growth substrate. The substrate includes a first surface, a second surface, and at least one via extending from the first surface to the second surface. The first surface or the second surface of the substrate directly contacts a surface of the growth substrate, and the surface of the growth substrate is electrically conductive. The method further includes disposing an electrolyte within the at least one via. The electrolyte includes metal ions of a metal to be deposited within the at least one via. The method also includes positioning an electrode within the electrolyte, and applying a current, a voltage, or a combination thereof between the electrode and the substrate, thereby reducing the metal ions into the metal on the surface of the growth substrate within the at least one via.

A second aspect according to the first aspect, further including removing the electrolyte from the substrate, and removing the growth substrate from the first surface or the second surface of the substrate.

A third aspect according to the first aspect or the second aspect, further including applying a mechanical force to substrate, the growth substrate, or both, to maintain direct contact between the substrate and the growth substrate.

A fourth aspect according to any preceding aspect, wherein an ambient temperature when the current, voltage or both is applied is between ten degrees Celsius and fifty degrees Celsius.

A fifth aspect according to any preceding aspect, wherein the growth substrate comprises an electrically conductive rubber material.

A sixth aspect according to any preceding aspect, wherein the growth substrate comprises an electrically conductive coating.

A seventh aspect according to the sixth aspect, wherein the electrically conductive coating includes one or more selected from the following: indium-tin oxide, copper coated indium-tin oxide, aluminum, aluminum coated indium-tin oxide, titanium, titanium coated indium-tin oxide, nickel, nickel coated indium-tin oxide, and niobium coated indium-tin oxide.

An eighth aspect according to any preceding aspect, wherein the growth substrate is a metal or a metal alloy.

A ninth aspect according to any preceding aspect, wherein the substrate comprises glass.

A tenth aspect according to the ninth aspect, wherein the glass is chemically strengthened such that the substrate has a first compressive stress layer and a second compressive stress layer both under compressive stress, and a central tension layer under tensile stress disposed between the first compressive stress layer and the second compressive stress layer.

An eleventh aspect according to any preceding aspect, wherein the metal is copper.

A twelfth aspect according to any preceding aspect, wherein the electrolyte comprises copper sulfate.

A thirteenth aspect according to any preceding aspect, wherein a current density range provided by the current is within a range of about 0.001 mA/cm² to about 1 A/cm².

A fourteenth aspect according to any preceding aspect, wherein, the voltage is within a range of about 0.001V to about −5V.

In a fifteenth aspect, a method of metalizing vias includes disposing a glass substrate onto a growth substrate. The glass substrate includes a first surface, a second surface, and at least one via extending from the first surface to the second surface. The first surface or the second surface of the glass substrate directly contacts a surface of the growth substrate. The surface of the growth substrate is electrically conductive. The method further includes applying a clamping force to the glass substrate and the growth substrate to maintain direct contact between the glass substrate and the growth substrate, and disposing an electrolyte within the at least one via, wherein the electrolyte comprises copper ions. The method also includes positioning an electrode within the electrolyte, and applying a current, a voltage, or a combination thereof between the electrode and the electrically conductive coating of the growth substrate, thereby reducing the copper ions into copper on the surface of the growth substrate within the at least one via. The method further includes removing the growth substrate from the first surface or the second surface of the glass substrate.

A sixteenth aspect according to the fifteenth aspect, wherein an ambient temperature when the current, voltage or both is applied is between fifteen degrees Celsius and fifty degrees Celsius.

A seventeenth aspect according to the fifteenth or sixteenth aspect, wherein the growth substrate comprises a metal or a metal alloy.

An eighteenth aspect according to any one of the fifteenth through seventeenth aspects, wherein the electrolyte comprises copper sulfate.

A nineteenth aspect according to any one of the fifteenth through eighteenth aspects, wherein a current density range provided by the current is within a range of about 0.001 mA/cm² to about 1 A/cm².

A twentieth aspect according to any one of the fifteenth through nineteenth aspects, the voltage is within a range of about 0.001V to about −5V.

Additional features and advantages of the embodiments described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts an example substrate and an example growth substrate in an uncoupled relationship according to one or more embodiments described and illustrated herein;

FIG. 2 schematically depicts the example substrate and the example growth substrate depicted in FIG. 1 in a coupled relationship, according to one or more embodiments described and illustrated herein;

FIG. 3 schematically depicts the example substrate and the example growth substrate depicted in FIG. 2 with an electrolyte disposed within example vias of the substrate, according to one or more embodiments described and illustrated herein;

FIG. 4 schematically depicts the example substrate, the example growth substrate, and the electrolyte depicted in FIG. 3 with a metal deposition front at a first surface of the growth substrate, according to one or more embodiments described and illustrated herein;

FIG. 5 schematically depicts the example substrate, the example growth substrate, and the electrolyte depicted in FIG. 3 with an advancing metal deposition front within the vias, according to one or more embodiments described and illustrated herein;

FIG. 6 schematically depicts the example substrate, the example growth substrate, and the electrolyte depicted in FIG. 3 with fully metalized vias, according to one or more embodiments described and illustrated herein;

FIG. 7 schematically depicts the example substrate of FIG. 6 removed from the example growth substrate depicted in FIGS. 1-6, according to one or more embodiments described and illustrated herein;

FIG. 8 schematically depicts an example via within a substrate and example forces therein, according to one or more embodiments described and illustrated herein;

FIG. 9 schematically depicts an example growth substrate coupled to an example substrate, and an example electroplating cell coupled to the substrate, according to one or more embodiments described and illustrated herein;

FIG. 10 graphically plots voltage versus time data for copper deposition with glass vias at a current of 5 mA; and

FIG. 11 is a photographic image of a glass substrate having copper filled vias by an example seedless electroplating process described and illustrated herein.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. Embodiments of the present disclosure are directed to metalizing vias of a substrate by a seedless electroplating process.

Embodiments bring a substrate (e.g., a glass substrate) with pre-patterned vias into contact with a smooth growth substrate having an electrically conductive surface, such as, without limitation, silicon or indium-tin oxide coated glass (ITO). An electrolyte containing the ions of the metal to be deposited (e.g., copper) is introduced into the vias followed by electrochemical reduction of the ions to metal particles on the growth substrate by applied current and/or voltage. Electrochemical deposition is continued until the vias are filled. Excess electrolyte is removed, and the substrate and the growth substrate are separated, thereby leaving the metal deposit in the vias. Embodiments do not require a seed layer accompanied with complicated void-mitigating strategies to fill the vias with metal. The embodiments of the present disclosure present a simpler and more inexpensive process than chemical vapor deposition (CVD) and paste-fill processes, and eliminate the need for curing. The processes described herein may be applied to any metal system that can be electrodeposited and to any through via technology, for example through-silicon vias or through glass vias.

Various methods of metalizing vias within a substrate are described in detail below.

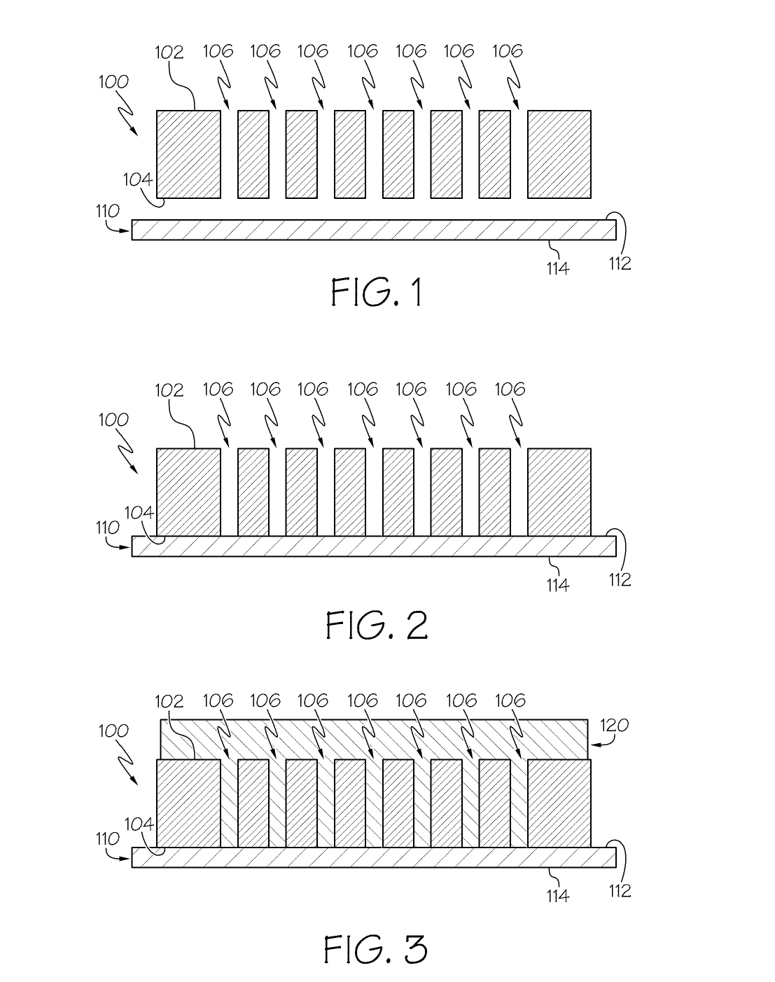

Referring now to FIG. 1, an example substrate 100 and an example growth substrate 110 are schematically illustrated in a de-coupled relationship. The substrate 100 may be fabricated from any material having at least one via 106 extending through the bulk of the substrate from a first surface 102 to a second surface 104. Example materials for the substrate 100 include, but are not limited to, silicon and glass. In one non-limiting example, the substrate 100 includes strengthened glass having a first compressive stress layer and a second compressive stress layer both under compressive stress, and a central tension layer under tensile stress disposed between the first compressive stress layer and the second compressive stress layer. The strengthened glass may be chemically strengthened, such as by an ion exchange strengthening process.

Although FIG. 1 illustrates a plurality of vias 106 extending through the substrate 100, embodiments are not limited thereto. In some embodiments, only one via may be provided, or multiple vias may be arranged in a manner different from what is illustrate in FIG. 1. Any number of vias in any configuration and arrangement may be provided.

The vias 106 may be formed from any known or yet-to-be-developed method. As a non-limiting example, the vias 106 may be formed by a laser damage and etch process wherein a pulsed laser is utilized to form damage regions within a bulk of the substrate 100. The substrate 100 is then subjected to a chemical etchant (e.g., hydrofluoric acid, potassium hydroxide, sodium hydroxide and the like). The material removal rate is faster in the laser damaged regions, thereby causing the vias 106 to open to a desired diameter. As an example and not a limitation, methods of fabricating vias in a substrate by laser damage and etching processes are described in U.S. Pub. No. 2015/0166395 which is hereby incorporated by reference in its entirety.

The growth substrate 110 provides a surface onto which metal ions are deposited during the electroplating process, as described above. Referring to FIG. 1, the growth substrate includes a first surface 112 and a second surface 114. In the example illustrated by FIG. 1, the first surface 112 of the growth substrate 110 provides the growth surface.

The growth substrate 110 may be any material (or layers of materials) that has an electrically conductive growth surface (e.g., first surface 112) smooth enough to enable metal detachment post deposition, and stable in the electrolyte 120 (described below). In one example, the growth substrate 110 is fabricated from a metal or metal alloy. Non-limiting metal materials include copper, stainless steel, titanium, nickel, and the like. Non-limiting metal alloys include brass, bronze, Inconel, and the like. In some embodiments, the growth substrate 110 may include a metal or metal alloy that is further coated with one or more coating layers.

In some embodiments, the growth substrate 110 comprises a dielectric material wherein the growth surface is coated with one or more electrically conductive coatings or layers. Example dielectric materials include, but are not limited to, rubber, silicon and glass. The one or more electrically conductive coatings or layers may be made of any suitable electrically conductive material. Example electrically conductive coating or layer materials include, but are not limited to, indium-tin oxide, copper coated indium-tin oxide, aluminum, aluminum coated indium-tin oxide, titanium, titanium coated indium-tin oxide, nickel, nickel coated indium-tin oxide, and niobium coated indium-tin oxide.

In yet another example, the growth substrate 110 may be fabricated from an electrically conductive rubber or polymer material having electrically conductive particles embedded therein.

As described below, the electrically conductive surface of the growth substrate 110 provides a growth surface during the electroplating process.

Referring now to FIG. 2, the second surface 104 of the substrate 100 is illustrated as being positioned in direct contact with the first surface 112 of the growth substrate. As used herein, “direct contact” means that the surfaces of substrates are in contact with one another without intervening layers disposed therebetween. In the illustrated example, the first surface 112 of the growth substrate 110 is the growth surface, and it is in direct contact with the second surface 104 of the substrate 100.

The substrate 100 and the growth substrate 110 are maintained in a coupled relationship as shown in FIG. 2 by the application of a mechanical force onto the substrate 100, the growth substrate 110, or both. The mechanical force provides a clamping force such that the second surface 104 of the substrate 100 remains in direct contact with the first surface 112 of the growth substrate 110. Non-limiting examples of devices for providing the mechanical force include one or more clamps and/or one or more weights. The mechanical force should be enough to prevent the electrolyte 120 (described below) from leaking between the substrate 100 and the growth substrate 110, but not so great that the substrate and/or the growth substrate 110 become damaged, such as by cracking. It is noted that using a rubber material with an electrically conductive surface as the growth substrate provides the added benefit of forming a seal between the second surface 104 of the substrate 100 and the first surface 112 of the growth substrate 110 due to the pliable nature of the rubber material.

Referring now to FIG. 3, an example electrolyte 120 applied to the example assembly of FIG. 2 is schematically illustrated. The electrolyte 120 contains the ions of the metal to be deposited on the first surface 112 (i.e., the growth surface) of the growth substrate 110 and within the vias 106. Although embodiments described herein refer to the metal to be deposited as copper, embodiments are not limited thereto. Example metals for deposition include, but are not limited to, silver, nickel, gold, platinum, and lead. The electrolyte may be sulfates, nitrates, or chlorides of any of the aforementioned metals. In one non-limiting example, the metal to be deposited is copper, and the electrolyte is copper sulfate. As a non-limiting example, the electrolyte 120 has a concentration of ions of 0.0001M or higher.

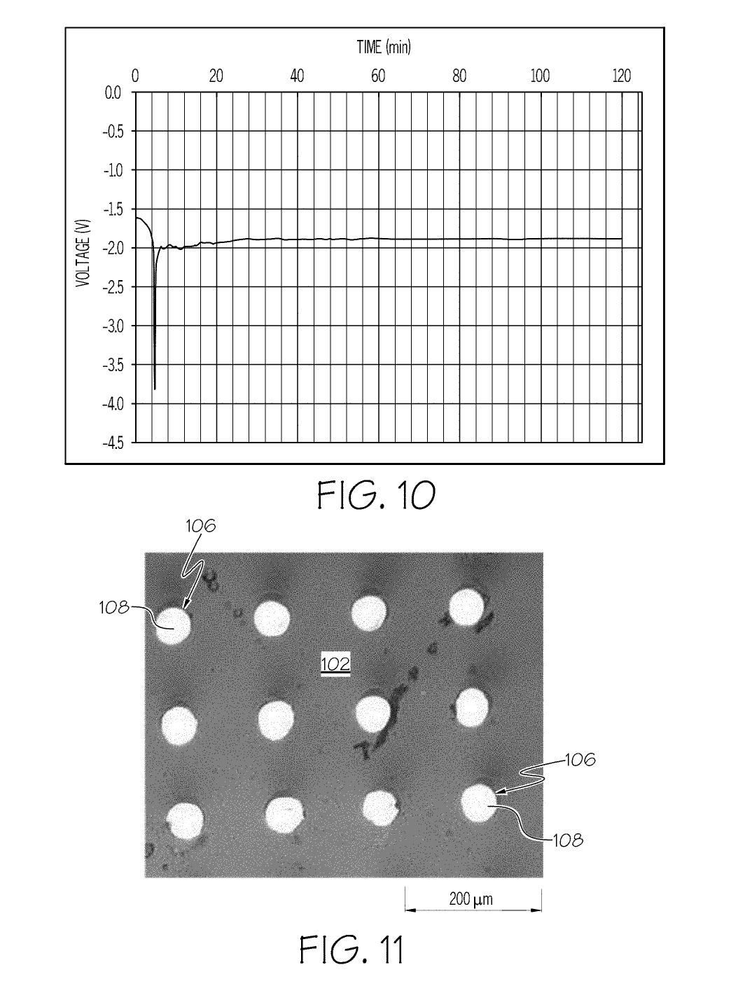

The electrolyte 120 is disposed about the substrate 100 such that it substantially fills all of the vias 106 that are present within the substrate 100. The electrolyte 120, the substrate 100, and the growth substrate 110 may be maintained within an electroplating cell 200, as illustrated in FIG. 10 and described in detail below. An electrode (i.e., a counter electrode) (not shown) is positioned within the electrolyte 120. The electrode may be fabricated from any electrically conductive material, such as, without limitation, platinum, copper, titanium, nickel, stainless steel, and the like. Current, voltage or a combination thereof is applied between the electrode and the growth surface (e.g., first surface 112) of the growth substrate 110 to provide a negative constant current to the growth substrate 110. As an example and not a limitation, a current density range of about 0.001 mA/cm² to about 1 A/cm² and a voltage range of about −0.001V to about −20V may be provided.

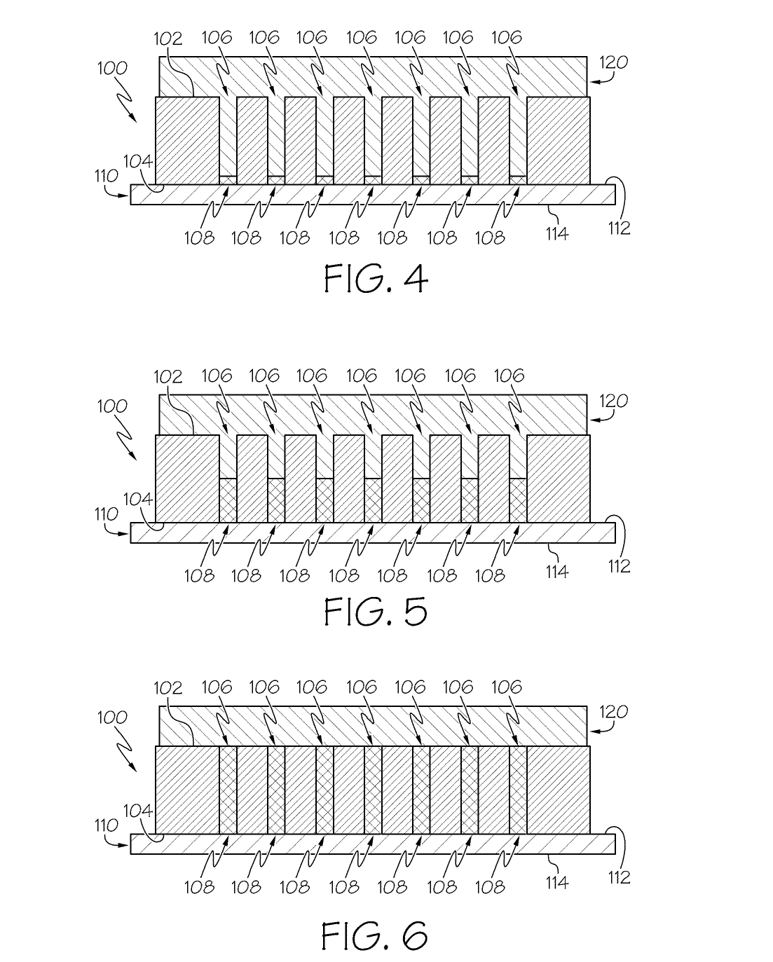

Referring to FIG. 4, this causes copper ions at the growth substrate 110-electrolyte 120 interface to get reduced as copper particles 108 on the first surface 112 of the growth substrate 110, where electrons from the first surface 112 of the growth substrate 110 are transferred to the copper ions to reduce them to metallic copper, as shown in Equation (1) below. It should be understood that ions other than copper ions may be provided in the electrolyte 120, as described above.

Cu_{electrolyte}²⁺+2e⁻→Cu_{solid,substrate}, Eq. (1).

The applied current controls the rate of this reduction reaction. Thus, the deposition rate may be increased or decreased by increasing or decreasing the applied current. However, it is noted that too high of an applied current may result in porous and void filled deposit, and too low a current may render the process too long to be practically useful. An optimal current density provides a dense, conductive coating in a reasonable amount of time.

The deposition process may be performed at room temperature, for example. As a non-limiting example, the deposition process may be performed at an ambient temperature between 10 degrees Celsius and 50 degrees Celsius.

Compared to traditional electroplating processes, the embodiments of the seedless plating process described herein provide for a copper deposition front that moves uniformly from the bottom of the via 106 to the top. In conventional seeded electroplating, the deposition front moves from all directions as copper is deposited everywhere on the sample including outside of the via. This phenomenon leads to closing of the mouth of the via before copper is entirely filled, trapping voids within the deposit. As the copper deposition front 108 moves in only one direction in the embodiments described herein, the process requirements are simple and also provide control of the deposit quality.

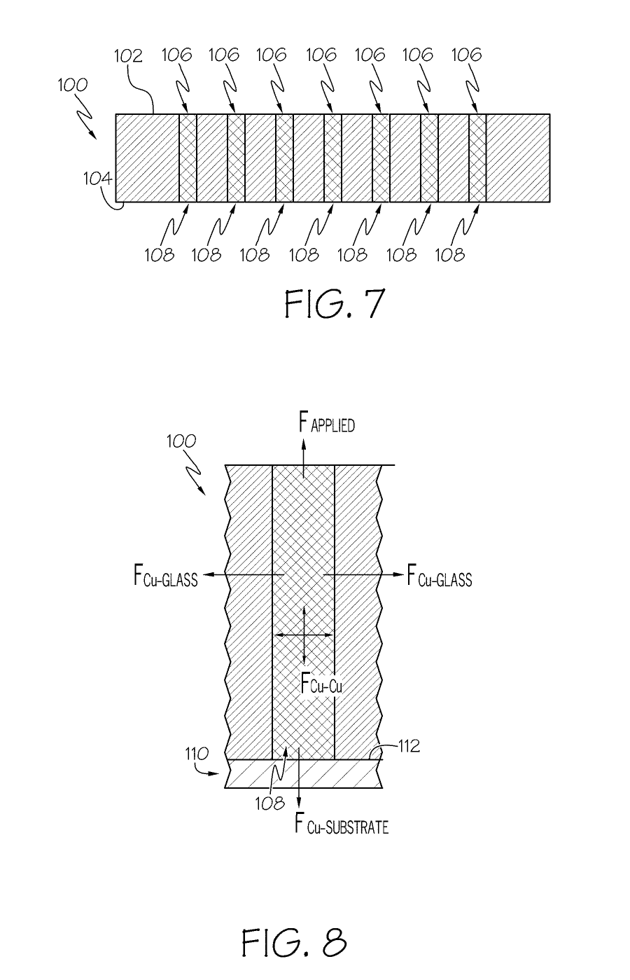

FIGS. 5 and 6 schematically depict the deposited copper particles 108 advancing in a direction from the first surface 112 of the growth substrate 110 toward the first surface 102 of the substrate 100. FIG. 6 schematically illustrates that the copper particles 108 have completely filled the vias 106. Once the vias 106 are filled with copper 108, the current is stopped and the electrolyte 120 is removed from the substrate 100. The mechanical force applied to the substrate 100 and/or the growth substrate 110 is removed, and the substrate 100 is separated from the growth substrate 110 leaving the metalized vias intact, as schematically illustrated in FIG. 7. The separation may occur using a slight mechanical force (i.e., pulling the substrate 100 apart from the growth substrate 110). Alternatively, heat or ultrasonic waves may be applied to separate the copper 108 and the substrate

Embodiments of the present disclosure may be enabled by the fact that the adhesive force between the deposited copper and the substrate 100 is smaller than the rest of the other forces in the system. FIG. 8 schematically illustrates the various forces acting on the copper 108 within the vias 196, which are:

F_{Cu-Substrate}—Adhesive force between the copper particles and the substrate;

F_{Cu-Cu}—Cohesive forces between the copper particles;

F_{Cu-Glass}—Adhesive force between the copper particles and the glass wall; and

F_{Applied}—Mechanical force applied after filling the via with copper.

Thus, the following condition should be satisfied for clean separation of the wafer from the substrate:

F_{Cu-Substrate}<F_{Cu-Cu}+F_{Cu-Glass}+F_{Applied} Eq. (2)

In some embodiments, the substrate 100 is cleaned, such as by rinsing with deionized water or other appropriate solution to remove residual electrolyte.

The substrate 100 may optionally be dried, such as by flowing a stream of nitrogen onto the substrate 100. The substrate 100 may be cleaned and dried while still in the cell and prior to separation from the growth substrate 110 in some embodiments. After separation from the growth substrate 110 and the optional cleaning and drying steps, the substrate 100 including one or more metalized vias may be then subjected to further downstream processes to incorporate it into the final product.

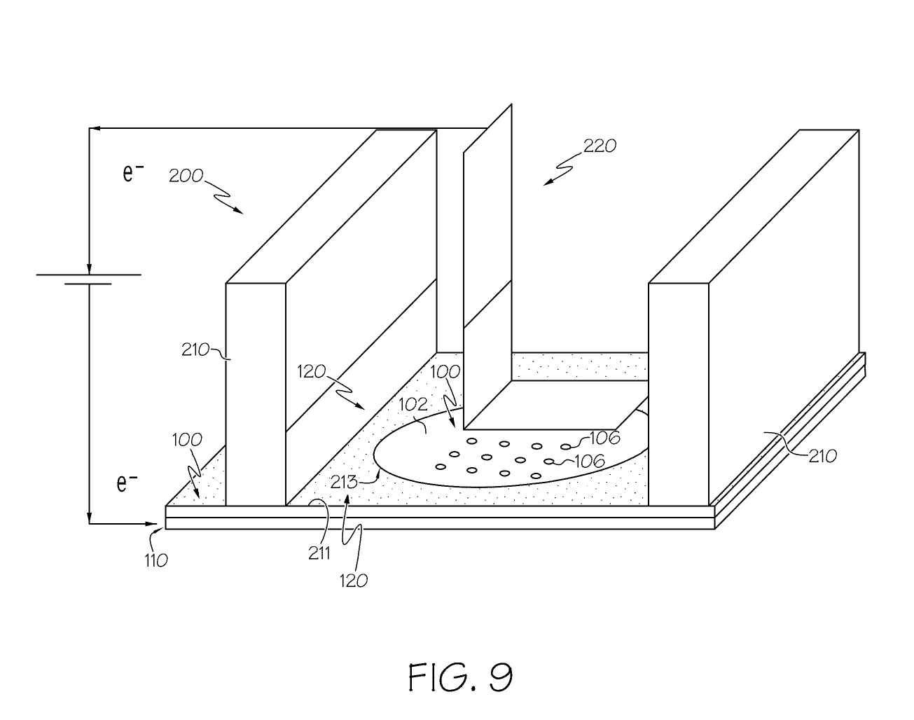

Referring now to FIG. 9, an example electroplating cell 200 according to one embodiment is schematically illustrated. The electroplating cell 200 is disposed on a first surface 102 of a substrate 100, such as the substrate 100 described above. The substrate 100 is coupled to a growth substrate 110, such as by an application of mechanical force, as described above. It is noted that that the electroplating cell 200 may also be maintained on the first surface 102 of the substrate 100 by the application of a mechanical force, such as by the use of one or more clamping devices, for example.

In the illustrated embodiment, the electroplating cell 200 comprises a plurality of walls 210. It should be understood that FIG. 9 illustrates only two walls 210 for illustrative purposes. It should also be understood that the shape and configuration of the walls 210 is not particularly limited. For example, one or more walls of the electroplating cell 210 may define an electroplating cell that is circular, elliptical, triangular, etc.

The example electroplating cell 200 includes a base layer 211 providing a floor that prevents electrolyte 120 from reaching portions of the first surface 102 of the substrate 100. The base layer 211 includes an opening 213 to expose a portion of the first surface 102 of the substrate 100 including vias 106 to the electrolyte 120. The base layer 211 is fabricated from Teflon in one non-limiting example. Other materials may be utilized. Electrolyte 120 is disposed within the electroplating cell 200 such that it substantially fills the vias 106. A counter electrode 220 is disposed within the electrolyte 120. As described above, a negative current is applied by way of the conductive growth substrate 110 and the counter electrode 220 until the desired metal is deposited within the vias 106. After the vias 106 have been filled, the electrolyte 120 may be removed from the electroplating cell 200 and the electroplating cell 200 be removed from the substrate 100, disassembled, and cleaned.

### Example

A 640 μm Corning® Gorilla® Glass 3 substrate manufactured by Corning, Incorporated of Corning, N.Y. having 60 μm diameter vias was used as the glass substrate. The growth substrate included an indium-tin oxide coated 0.7 mm thick borosilicate glass substrate that had a 200 nm niobium coating. A 1.2M copper sulfate was used as the electrolyte.

FIG. 10 graphically illustrates the voltage vs. time behavior during copper deposition at a constant current of 5 mA for 2 hours. Copper atoms first nucleated on the niobium coated substrate. As these particles grew, there was an increase in voltage. After the initial particles are formed, further nucleation and growth happens on both the uncovered niobium surface and the already deposited copper particles within the vias. Without being bound by theory, during this phase, the measure voltage represents the thermodynamics of the reactions happening on the niobium coated surface and the surface provided by the copper that was deposited once the current was applied. Once the niobium is completely covered with copper, the voltage settled down to a stable value, during which there was nucleation and growth of copper only on the already deposited copper particles. It is noted that, as the deposition front moves upward, the electrolyte is pushed out of the vias. FIG. 11 is an image of the glass substrate having copper 108 deposited within the vias 106.

As there are no solid reaction by-products in this process, the electrolyte remains fairly clean and free of any contamination enabling it to be reused multiple times, if desired.

It should now be understood that embodiments described herein are directed to methods for filling vias of a substrate with a metal using a seedless electroplating process. The methods described herein enable vias to be metalized at room temperature, do not utilize a seed layer to be deposited, and do not require the bonding of the substrate to a seed layer.

It will be apparent to those skilled in the art that various modifications and variations can be made to the embodiments described herein without departing from the spirit and scope of the claimed subject matter. Thus it is intended that the specifications cover the modifications and variations of the various embodiments described herein provided such modification and variations come within the scope of the appended claims and their equivalents.

What is claimed is:

1. A method of metalizing vias, the method comprising:
disposing a substrate onto a growth substrate, wherein:
the substrate comprises a first surface, a second surface, and at least one via extending from the first surface to the second surface;
the first surface or the second surface of the substrate directly contacts a surface of the growth substrate; and
the surface of the growth substrate is electrically conductive;
disposing an electrolyte within the at least one via, wherein the electrolyte comprises metal ions of a metal to be deposited within the at least one via;
positioning an electrode within the electrolyte; and
applying a current, a voltage, or a combination thereof between the electrode and the substrate, thereby reducing the metal ions into the metal on the surface of the growth substrate within the at least one via.

2. The method of claim 1, further comprising:
removing the electrolyte from the substrate; and
removing the growth substrate from the first surface or the second surface of the substrate.

3. The method of claim 1, further comprising applying a mechanical force to substrate, the growth substrate, or both, to maintain direct contact between the substrate and the growth substrate.

4. The method of claim 1, wherein an ambient temperature when the current, voltage or both is applied is between ten degrees Celsius and fifty degrees Celsius.

5. The method of claim 1, wherein the growth substrate comprises an electrically conductive rubber material.

6. The method of claim 1, wherein the growth substrate comprises an electrically conductive coating.

7. The method of claim 6, wherein the electrically conductive coating comprises one or more selected from the following: indium-tin oxide, copper coated indium-tin oxide, aluminium, aluminium coated indium-tin oxide, titanium, titanium coated indium-tin oxide, nickel, nickel coated indium-tin oxide, and niobium coated indium-tin oxide.

8. The method of claim 1, wherein the growth substrate comprises a metal or a metal alloy.

9. The method of claim 1, wherein the substrate comprises glass.

10. The method of claim 9, wherein the glass is chemically strengthened such that the substrate has a first compressive stress layer and a second compressive stress layer both under compressive stress, and a central tension layer under tensile stress disposed between the first compressive stress layer and the second compressive stress layer.

11. The method of claim 1, wherein the metal is copper.

12. The method of claim 1, wherein the electrolyte comprises copper sulfate.

13. The method of claim 1, wherein a current density range provided by the current is within a range of about 0.001 mA/cm² to about 1 A/cm².

14. The method of claim 1, wherein the voltage is within a range of about 0.001V to about −20V.

15. A method of metalizing vias, the method comprising:
disposing a glass substrate onto a growth substrate, wherein:
the glass substrate comprises a first surface, a second surface, and at least one via extending from the first surface to the second surface;
the first surface or the second surface of the glass substrate directly contacts a surface of the growth substrate; and
the surface of the growth substrate is electrically conductive;
applying a clamping force to the glass substrate and the growth substrate to maintain direct contact between the glass substrate and the growth substrate;
disposing an electrolyte within the at least one via, wherein the electrolyte comprises copper ions;
positioning an electrode within the electrolyte;
applying a current, a voltage, or a combination thereof between the electrode and the electrically conductive coating of the growth substrate, thereby reducing the copper ions into copper on the surface of the growth substrate within the at least one via; and
removing the growth substrate from the first surface or the second surface of the glass substrate.

16. The method of claim 15, wherein an ambient temperature when the current, voltage or both is applied is between fifteen degrees Celsius and fifty degrees Celsius.

17. The method of claim 15, wherein the growth substrate comprises a metal or a metal alloy.

18. The method of claim 15, wherein the electrolyte comprises copper sulfate.

19. The method of claim 15, wherein a current density range provided by the current is within a range of about 0.001 mA/cm² to about 1 A/cm².

20. The method of claim 15, the voltage is within a range of about 0.001V to about −20V.
